(19) United States
(12) Patent Application Publication
(10) Pub. No.: US 2024/0339923 A1
(43) Pub. Date: Oct. 10, 2024

(54) GATE DRIVER

(71) Applicant: Enphase Energy, Inc., Petaluma, CA (US)

(72) Inventor: Michael J. HARRISON, Petaluma, CA (US)

(21) Appl. No.: 18/603,968

(22) Filed: Mar. 13, 2024

Related U.S. Application Data
(60) Provisional application No. 63/457,595, filed on Apr. 6, 2023.

(51) Int. Cl. H02M 1/088; H02M 3/335

(52) U.S. Cl. CPC H02M 1/088; H02M 3/33573; H02M 3/33584

(57) ABSTRACT

A cycloconverter configured for use with a power converter is provided herein and comprises a bidirectional switch comprising a pair of Gallium-Nitride (GaN) High Electron Mobility Transistors and a Gate driver coupled to a gate of each of the pair of Gallium-Nitride (GaN) High Electron Mobility Transistors and configured to provide at least one of independent turn-on and turn-off outputs for implementing asymmetrical Gate drive characteristics, a voltage regulated supply to determine a gate turn-on voltage, and a gate turn-off voltage supply that can sink and source current.

### CROSS-REFERENCE TO RELATED APPLICATIONS

The present application claims the benefit of and priority to U.S. Provisional Application Ser. No. 63/457,595, filed on Apr. 6, 2023, the entire contents of which is incorporated herein by reference.

### BACKGROUND

### Field of the Disclosure

Embodiments of the present disclosure relate generally to power conversion systems and, for example, to a universal GaN HEMT Gate driver configured for use with power converters.

### Description of the Related Art

Conventional power converters suitable for use with power conversion systems are known. The power converters can comprise one or more cycloconverters that comprise one or more switches that are driven by a gate driver connected to one or more GaN HEMT (High Electron Mobility Transistor) devices that are connected to the one or more switches.

The GaN HEMT (High Electron Mobility Transistor) devices are gaining popularity to replace conventional Si Super-Junction (SJ) MOSFET devices. The Gate drive requirements for GaN HEMT are specifically different to Si SJ MOSFETS, which is also compounded by the fact that there are actually three different competing technologies for GaN HEMT devices (e.g., Cascode, Gate Injection Transistor (GIT), and the Schottky Gate) in that each have their own unique drive requirements.

For example, the Si Super-Junction MOSFET (e.g., the Si SJ MOSFET device) features a Gate threshold voltage that is typically about 4V, a recommended drive voltage of around 9V to 12V, and an absolute maximum Gate drive voltage of around 18V. The drive characteristics have made Si SJ MOSFETs relatively easy to drive effectively. The high Gate threshold allows the Si SJ MOSFETs to be reliably turned-off using a zero Gate turn-off voltage and the significant margin between the recommended Gate drive voltage and the absolute maximum Gate drive voltage eliminates the need to employ any voltage regulator for the Gate driver supply voltage.

Conversely, the enhancement mode eHEMT device, which features a Schottky Gate structure, has a Gate threshold of about 1V, a recommended drive voltage of 5V, and an absolute maximum Gate drive voltage of 7V. The difference in voltages between the Si Super-Junction MOSFET and the enhancement mode eHEMT device illustrates the need for the contrast between these types of power semiconductor devices and, hence, the need for a different Gate driver device.

Thus, there is a need for improved power conversion systems comprising a universal GaN HEMT Gate driver configured for use with power converters.

### SUMMARY

In accordance with at least some embodiments, a cycloconverter configured for use with a power converter comprises a bidirectional switch comprising a pair of Gallium-Nitride (GaN) High Electron Mobility Transistors and a Gate driver coupled to a gate of each of the pair of Gallium-Nitride (GaN) High Electron Mobility Transistors and configured to provide at least one of independent turn-on and turn-off outputs for implementing asymmetrical Gate drive characteristics, a voltage regulated supply to determine a gate turn-on voltage, and a gate turn-off voltage supply that can sink and source current.

In accordance with at least some embodiments, a power conversion system comprises a converter, a DC component coupled to a DC side of the converter, a plurality of switches coupled to a primary winding of a transformer, and a cycloconverter coupled to a secondary winding of the transformer and comprising a bidirectional switch comprising a pair of Gallium-Nitride (GaN) High Electron Mobility Transistors and a Gate driver coupled to a gate of each of the pair of Gallium-Nitride (GaN) High Electron Mobility Transistors and configured to provide at least one of independent turn-on and turn-off outputs for implementing asymmetrical Gate drive characteristics, a voltage regulated supply to determine a gate turn-on voltage, and a gate turn-off voltage supply that can sink and source current.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of a power conversion system comprising a switched mode power converter, in accordance with embodiments of the present disclosure;

FIG. 2 is a schematic diagram of a power conversion system comprising a switched mode power converter, in accordance with embodiments of the present disclosure; and

FIG. 3 is a schematic diagram of a universal gate driver, in accordance with embodiments of the present disclosure.

### DETAILED DESCRIPTION

Embodiments of the present disclosure are directed to improved power conversion systems comprising a universal GaN HEMT Gate driver configured for use with power converters. For example, a cycloconverter configured for use with a power converter can comprise a bidirectional switch comprising a pair of Gallium-Nitride (GaN) High Electron Mobility Transistors. A Gate driver coupled to a gate of each of the pair of Gallium-Nitride (GaN) High Electron Mobility Transistors is configured to provide at least one of independent turn-on and turn-off outputs for implementing asymmetrical Gate drive characteristics, a voltage regulated supply to determine a gate turn-on voltage, and a gate turn-off voltage supply that can sink and source current. Apparatus described herein enable a single microinverter design to accommodate GaN HEMT devices from multiple different manufacturers without requiring separate inverter designs for each different GaN HEMT. Additionally, apparatus described herein simplify the manufacturing process with regard to the need to support multiple different suppliers for all critical microinverter components.

The foregoing description of embodiments of the disclosure comprises a number of elements, devices, circuits and/or assemblies that perform various functions as described. These elements, devices, circuits, and/or assemblies are exemplary implementations of means for performing their respectively described functions.

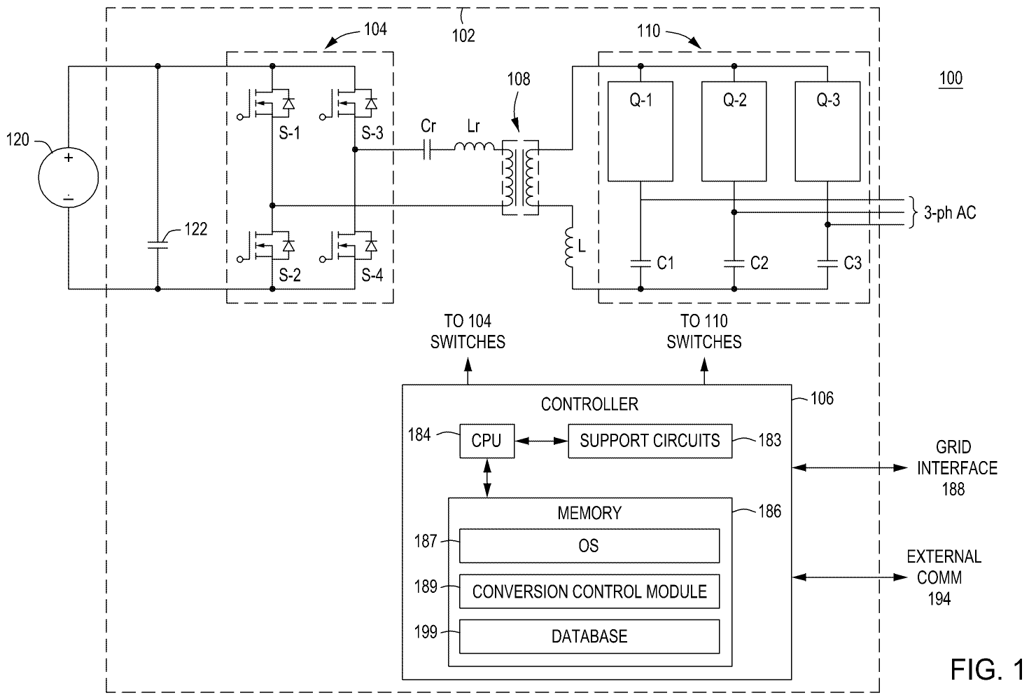

FIG. 1 is a schematic diagram of a power conversion system 100 comprising a converter 102 (e.g., a switched mode power converter), in accordance with embodiments of the present disclosure. This diagram only portrays one variation of the myriad of possible system configurations. The present disclosure can function in a variety of power generation environments and systems.

The power conversion system 100 comprises a DC component 120, such as a PV module or a battery, coupled to a DC side of the converter 102 (referred to herein as “converter 102”). In other embodiments the DC component 120 may be any suitable type of DC components, such as another type of renewable energy source (e.g., wind farms, hydroelectric systems, and the like), other types of energy storage components, and the like.

The converter 102 comprises a capacitor 122 coupled across the DC component 120 as well as across an H-bridge 104 formed from switches S-1, S-2, S-3 and S-4. The switches S-1 and S-2 are coupled in series to form a left leg of the H-bridge 104, and the switches S-3 and S-4 are coupled in series to form a right leg of the H-bridge 104.

The output of the H-bridge 104 is coupled across a series combination of a capacitor Cr and inductor L, which form a resonant tank, and the primary winding of a transformer 108. In other embodiments, the resonant tank may be formed by a different configuration of the capacitor Cr and the inductor Lr (e.g., the capacitor Cr and the inductor L may be coupled in parallel); in some embodiments, Lr may represent a leakage inductance from the transformer 108 rather than a physical inductor.

A series combination of the secondary winding of the transformer 108 and an inductor L is coupled across a cycloconverter 110 which produces a three-phase AC output, although in other embodiments the cycloconverter 110 may produce one or two phases of AC at its output. The cycloconverter can be a bridge of unidirectional switches (which can conduct current in one direction when turned on) or bidirectional switches (which can conduct current in either direction when turned on) that are able to process AC energy. For illustrative purposes, the cycloconverter is shown as a bridge comprising bidirectional switches that can conduct current in either direction (when turned on), can block a voltage of either polarity (when turned off), and can also block a voltage in both polarities. The cycloconverter 110 comprises three 4Q bi-directional switches Q-1, Q-2, and Q-3 (which may be collectively referred to as switches Q) respectively in a first leg, a second leg, and a third leg coupled in parallel to one another. In accordance with embodiments of the present disclosure, each of the switches Q-1, Q-2, and Q-3 is a native four quadrant bi-directional switch comprising one or more Gallium-Nitride (GaN) High Electron Mobility Transistors, as described in greater detail below. In at least some embodiments, each of the switches Q-1, Q-2, and Q-3 comprises a pair of Gallium-Nitride (GaN) High Electron Mobility Transistors. In at least some embodiments, each of the switches Q-1, Q-2, and Q-3 comprises a first pair of Gallium-Nitride (GaN) High Electron Mobility Transistors and a second pair of Gallium-Nitride (GaN) High Electron Mobility Transistors. In at least some embodiments, the Gallium-Nitride (GaN) High Electron Mobility Transistors can be monolithically integrated bidirectional switches (MBDS).

The first cycloconverter leg comprises the 4Q switch Q-1 coupled to a capacitor C1, the second cycloconverter leg comprises the 4Q switch Q-2 coupled to a capacitor C2, and the third cycloconverter leg comprises a 4Q switch Q-3 coupled to a capacitor C3. A first AC output phase line is coupled between the switch Q-1 and the capacitor C1, a second AC output phase line is coupled between the switch Q-2 and the capacitor C2, and a third AC output phase line is coupled between the switch Q-3 and the capacitor C3. The converter 102 may also include additional circuitry not shown, such as voltage and/or current monitors, for obtaining data for power conversion, data reporting, and the like.

The converter 102 additionally comprises a controller 106 coupled to the H-bridge switches (S-1, S-2, S-3, and S-4) and the cycloconverter switches (Q-1, Q-2, and Q-3) for operatively controlling the switches to generate the desired output power. In some embodiments, the converter 102 may function as a bi-directional converter.

The controller 106 comprises a CPU 184 coupled to each of support circuits 183 and a memory 186. The CPU 184 may comprise one or more conventionally available microprocessors or microcontrollers. Additionally or alternatively, the CPU 184 may include one or more application specific integrated circuits (ASICs). The support circuits 183 are well known circuits used to promote functionality of the CPU 184. Such circuits include, but are not limited to, a cache, power supplies, clock circuits, buses, input/output (I/O) circuits, and the like. The controller 106 may be implemented using a general purpose computer that, when executing particular software, becomes a specific purpose computer for performing various embodiments of the present disclosure.

The memory 186 is a non-transitory computer readable storage medium such as random access memory, read only memory, removable disk memory, flash memory, and various combinations of these types of memory. The memory 186 is sometimes referred to as main memory and may, in part, be used as cache memory or buffer memory. The memory 186 generally stores the OS 187 (operating system), if necessary, of the controller 106 that can be supported by the CPU capabilities. In some embodiments, the OS 187 may be one of a number of commercially available operating systems such as, but not limited to, LINUX, Real-Time Operating System (RTOS), and the like.

The memory 186 may store various forms application software (e.g., instructions), such as a conversion control module 189 for controlling power conversion by the converter 102, for example maximum power point tracking (MPPT), switching, performing the methods described herein, and the like. The memory 186 may further store a database 199 for storing various data. The controller 106 further processes inputs and outputs to external communications 194 (i.e., gateway) and a grid interface 188.

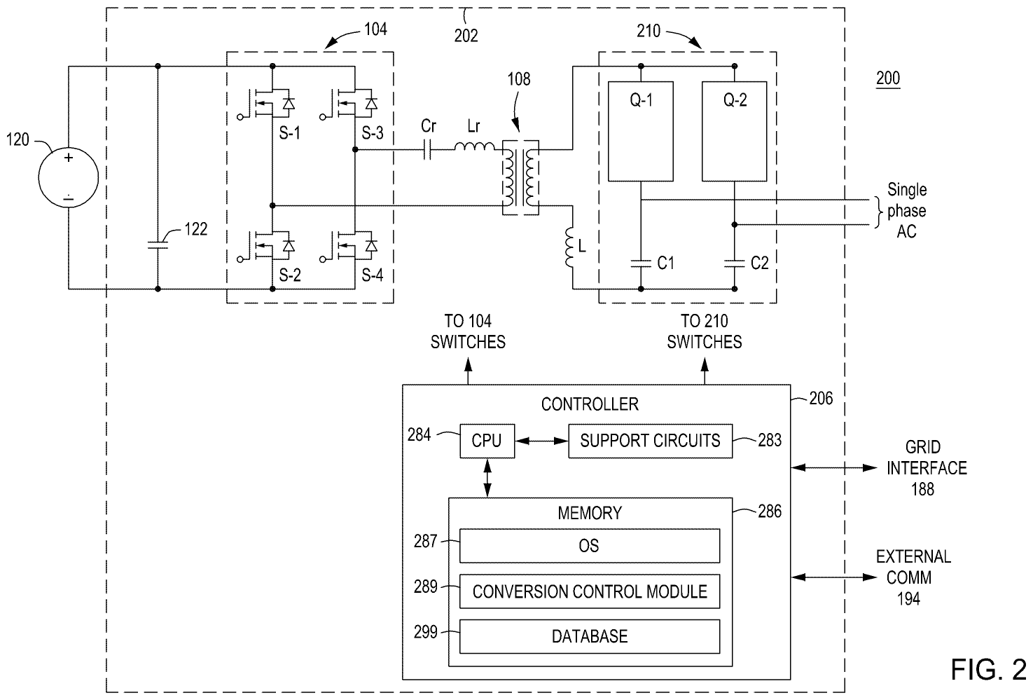

FIG. 2 is a schematic diagram of a power conversion system 200 comprising a converter 202 (e.g., a switched mode power converter), in accordance with embodiments of the present disclosure.

The power conversion system 200 comprises the DC component 120 coupled to a DC side of the converter 202. The converter 202 comprises the capacitor 122 coupled across the DC component 120 and the H-bridge 104, as described above with respect to the converter 102. The output of the H-bridge 104 is coupled across a series combination of the capacitor Cr and the inductor Lr, which form a resonant tank, and the primary winding of the transformer 108, as described above with respect to the converter 102. In other embodiments, the resonant tank may be formed by a different configuration of the capacitor Cr and the inductor Lr (e.g., the capacitor Cr and the inductor L may be coupled in parallel); in some embodiments, Lr may represent a leakage inductance of the transformer 108 rather than a physical inductor.

A series combination of the secondary winding of the transformer 108 and the inductor L is coupled across a cycloconverter 210 which produces a single-phase AC output. As described above with respect to the converter 102, the cycloconverter can be a bridge of unidirectional switches (which can conduct current in one direction when turned on) or bidirectional switches (which can conduct current in either direction when turned on) that are able to process AC energy. For illustrative purposes, the cycloconverter is shown as a bridge comprising bidirectional switches. For example, the cycloconverter 210 comprises two bi-directional switches Q-1 and Q-2, (collectively referred to as switches Q) respectively in a first leg and a second leg coupled in parallel to one another. In accordance with embodiments of the present disclosure, each of the switches Q-1 and Q-2 is a native four quadrant bi-directional switch comprising Gallium-Nitride (GaN) High Electron Mobility Transistors. In at least some embodiments, each of the switches Q-1, Q-2, and Q-3 comprises a pair of Gallium-Nitride (GaN) High Electron Mobility Transistors. In at least some embodiments, each of the switches Q-1, Q-2, and Q-3 comprises a first pair of Gallium-Nitride (GaN) High Electron Mobility Transistors and a second pair of Gallium-Nitride (GaN) High Electron Mobility Transistors. In at least some embodiments, the Gallium-Nitride (GaN) High Electron Mobility Transistors can be monolithically integrated bidirectional switches (MBDS).

The first cycloconverter leg comprises the 4Q switch Q-1 coupled to the capacitor C1, and the second cycloconverter leg comprises the 4Q switch Q-2 coupled to the capacitor C2. A first AC output phase line is coupled between the switch Q-1 and the capacitor C1, and a second AC output phase line is coupled between the switch Q-2 and the capacitor C2. The converter 202 may also include additional circuitry not shown, such as voltage and/or current monitors, for obtaining data for power conversion, data reporting, and the like.

The converter 202 additionally comprises a controller 206 coupled to the H-bridge switches (S-1, S-2, S-3, and S-4), and the cycloconverter switches (Q-1 and Q-2) for operatively controlling the switches to generate the desired output power. In some embodiments, the converter 202 may function as a bi-directional converter.

The controller 206 comprises a CPU 284 coupled to each of support circuits 283 and a memory 286. The CPU 284 may comprise one or more conventionally available microprocessors or microcontrollers. Additionally or alternatively, the CPU 284 may include one or more application specific integrated circuits (ASICs). The support circuits 283 are well known circuits used to promote functionality of the CPU 284. Such circuits include, but are not limited to, a cache, power supplies, clock circuits, buses, input/output (I/O) circuits, and the like. The controller 206 may be implemented using a general purpose computer that, when executing particular software, becomes a specific purpose computer for performing various embodiments of the present disclosure.

The memory 286 is a non-transitory computer readable medium such as random access memory, read only memory, removable disk memory, flash memory, and various combinations of these types of memory. The memory 286 is sometimes referred to as main memory and may, in part, be used as cache memory or buffer memory. The memory 286 generally stores the OS 287 (operating system), if necessary, of the controller 206 that can be supported by the CPU capabilities. In some embodiments, the OS 287 may be one of a number of commercially available operating systems such as, but not limited to, LINUX, Real-Time Operating System (RTOS), and the like.

The memory 286 may store various forms of application software, such as a conversion control module 289 for controlling power conversion by the converter 202, for example maximum power point tracking (MPPT), switching, and the like. The memory 286 may further store a database 299 for storing various data. The controller 206 further processes inputs and outputs to external communications 194 (i.e., gateway) and the grid interface 188.

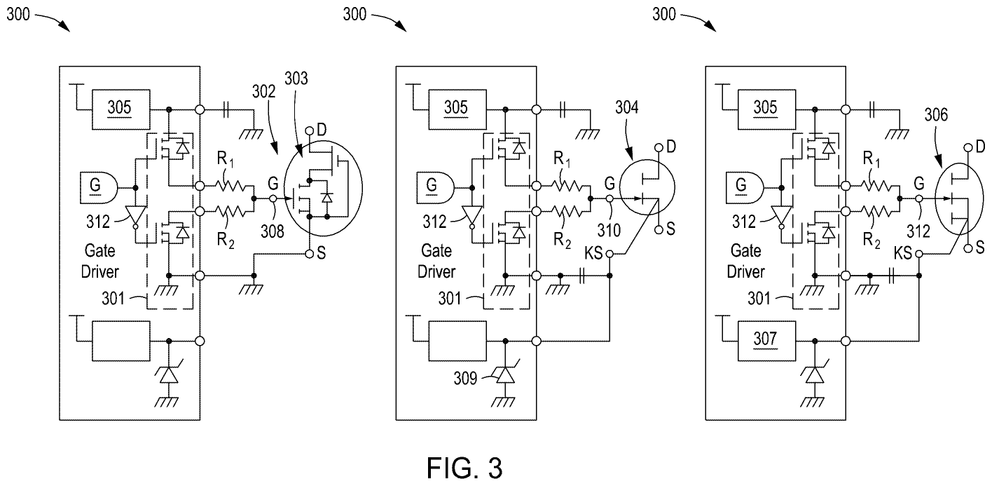

FIG. 3 is a schematic diagram of a universal gate driver 300 (e.g., GaN Gate driver), in accordance with embodiments of the present disclosure. The universal gate driver 300 is configured for use with one or more GaN HEMT devices (e.g., one or more of the unidirectional switches or bi-directional switches Q-1, Q-2, or Q-3). Accordingly, the universal gate driver 300 is configured to provide an asymmetrical turn-on and turn-off capabilities. For example, the universal gate driver 300 is configured to provide independent turn-on and turn-off output. For example, a turn-on output pin can pull up to the Gate G drive supply voltage when the Gate G driver is turned on, and, conversely, a turn-off output pin can pull down to the Gate G driver ground when the Gate G driver is turned off. Separate Gate G turn-on and turn-off resistors R₁ and R₂, respectively, can be used to connect the Gate G driver outputs to the negative transistor Gate 308 (an external Gate), thus, providing an asymmetrical drive while eliminating the use of an external diode and the external diode's associated forward voltage drop.

Continuing with reference to FIG. 3, the universal gate driver 300 is shown configured for use with three different types of GaN HEMT devices. For example, the universal gate driver 300 is shown connected a Cascode GaN HEMT device 302, which is a fusion of a normally on (depletion mode) GaN HEMT connected to a low voltage normally off silicon (Si) MOSFET 303 to provide a required normally off system behavior. Accordingly, driving the Cascode GaN HEMT device 302 closely resembles a drive for a conventional Si MOSFET on the basis that the Cascode GaN HEMT device 302 is actually a Si MOSFET Gate. For example, the transistor Gate 308 input resembles a capacitor and the transistor Gate 308 threshold voltage is, typically, around 4V with the transistor Gate 308 drive voltage of about 9V to about 12V and with a maximum transistor Gate 308 drive voltage of about 16V to about 18V (a maximum voltage). The Cascode GaN HEMT device 302 does not require a negative transistor Gate 308 turn-off voltage, as a 0V turn-on is adequate to ensure the Cascode GaN HEMT device 302 is turned fully off. Further, the use of a negative transistor Gate 308 turn-off voltage unnecessarily increases the required external transistor Gate 308 charge, which is already much higher (approximately 4×) for the Cascode GaN HEMT device 302 compared to a gate injection transistor (GIT) GaN HEMT device 304 and a Schottky Gate GaN eHEMT device 306, as described in greater detail below.

In operation, a Gate drive logic signal that is present at the output Gate G drives a pair of driver transistors 301 comprising an upper drive transistor and a lower drive transistor. The upper drive transistor is driven directly by the Gate drive logic signal at the output of gate G and the lower drive transistor is driven via a logic inverter 312. Such a configuration allows one of the upper drive transistor or the lower drive transistor to be on while the other is off. For example, when the Gate drive logic signal at the output of G is low, the upper drive transistor will be turned off and the lower drive transistor will be turned on, which results in the transistor Gate 308 being turned off via the turn-off resistor R₂, which is connected to the universal gate driver 300 local GND via the Gate turn-off driver transistor. Conversely, when the Gate drive logic signal at the output of G is high, the upper drive transistor will be turned on and the lower drive transistor will be turned off, which results in the transistor Gate 308 being turned on via the turn-on resistor R₁, which is supplied by a voltage regulator supply 305, such that the voltage provided to the transistor Gate 308 turn-on resistor R₁ will be equal to a set voltage of the voltage regulator supply 305. In at least some embodiments, the upper drive transistor and the lower drive transistor can be implemented in a silicon ASIC that performs the universal gate driver 300 operation, and, hence, the upper drive transistor and the lower drive transistor can be Si MOSFETs, i.e., FIG. 3 shows the upper drive transistor and the lower drive transistor as Si MOSFETs, hence the body diode of the Si MOSFET is shown.

A Source S of the Cascode GaN HEMT device 302 is connected to a local GND of the universal gate driver 300, which results in a zero Gate G turn off voltage when the lower drive transistor turns on. Additionally, a Kelvin Source KS of the GIT GaN HEMT device 304 and the Kelvin Source KS of the Schottky Gate GaN eHEMT device 306 are connected to a 1.5V voltage regulator 307 of the universal gate driver 300, which results in the Gate G turn-off voltage for the GIT GaN HEMT device 304 and the Schottky Gate GaN eHEMT device 306 being driven to −1.5V when the lower drive transistor turns on. The 1.5V voltage regulator 307 is able to both source current to meet the requirements for the Schottky Gate GaN eHEMT device 306 and sink current to meet the requirements for the GIT GaN HEMT device 304.

Continuing with reference to FIG. 3, as noted above, the universal gate driver 300 is configured for use with the GIT GaN HEMT device 304, which features a junction Gate 310 that requires a drive voltage of about 1.2V and a sustained typical junction Gate 310 current of about 1 mA to about 10 mA. The junction Gate 310 is driven from the universal gate driver 300 via a resistor (e.g., resistor R₁) to limit (set) the required junction Gate 310 drive current. Accordingly, the GIT GaN HEMT device 304 junction Gate 310 drive solution does not require a well-regulated junction Gate 310 drive voltage (e.g., similar to the Si MOSFET). Since the junction Gate 310 threshold voltage is so low (e.g., typically, 1.2V, and getting as low as 0.7V at 125° C.) a negative junction Gate 310 turn-off voltage (e.g., via resistor R₂) is required to ensure that the GIT GaN HEMT device 304 can be reliably turned off. Due to the junction Gate 310 impact, the negative junction Gate 310 turn-off supply needs to be configured to sink current (e.g., via a Zener diode 309 or another device suitable for sinking current, e.g., via the voltage regulator 307).

Likewise, the universal gate driver 300 is configured for use with the Schottky Gate GaN eHEMT device 306, which features a junction Gate 310 structure that appears to be a capacitor with a junction Gate 310 threshold of about 1V to about 2V, but requires an applied voltage of about 5V to fully turn the device on and an absolute maximum junction Gate 310 voltage (field effect) of about 7V. The junction Gate 310 drive solution for driving the Schottky Gate GaN eHEMT device 306 needs to be well-regulated to achieve a recommended junction Gate 310 drive voltage (e.g., field effect) without endangering the Schottky Gate GaN eHEMT device 306 due to the junction Gate 310 drive over-voltage. As with the GIT GaN HEMT device 304, since the junction Gate 310 threshold voltage for the Schottky Gate GaN eHEMT device 306 is so low (e.g., typically, 1.2V, and getting as low as 0.7V at 125° C.), a negative junction Gate 310 turn-off voltage (e.g., via resistor R₂) is required to ensure that the Schottky Gate GaN eHEMT device 306 can be reliably turned off. Unlike the GIT GaN HEMT device 304, however, due to the junction Gate 310 impact (e.g., capacitive field effect), the negative junction Gate 310 turn-off supply needs to be configured to source current, e.g., via the 1.5 voltage regulator 307 or another device suitable for sourcing current).

The inventor has found that by combining the individual requirements for driving each type of the GaN HEMT devices, a common set of requirements for the universal gate driver 300 can be determined. For example, in at least some embodiments, the universal gate driver 300 has independent turn-on and turn-off outputs (connected to respective Resistors R₁ and R₂) for implementing asymmetrical Gate drive characteristics, has a voltage regulator supply 305 (e.g., adjustable/programmable) to determine a Gate turn-on voltage, and an optional negative Gate turn-off voltage supply that can both sink (e.g., via the Zener diode 309) and source current (e.g., via the voltage regulator 307). Moreover, the universal gate driver 300 is also suitable for driving conventional Si MOSFETS (or IGBTs) on the basis that the Cascode GaN HEMT device 302 utilizes a Si MOSFET to drive the Cascode GaN HEMT device 302.

The universal gate driver 300 allows for the use of any of the three types of GaN HEMT devices (e.g., mix and match) in power converters, which mitigates GaN HEMT supply chain issues. For example, as noted above, a single PCB design can be created for a power converter (e.g., microinverter) that employs the universal gate driver 300 and the single PCB design can be used to employ all three different types of GaN HEMT devices in the power converter, which can provide significant engineering cost saving by not having to support only a single GaN HEMT device. For example, the single PCB design can comprise the universal gate driver 300 comprising all of the components needed for each of the Cascode GaN HEMT device 302, the GIT GaN HEMT device 304, and Schottky Gate GaN eHEMT device 306.

While the foregoing is directed to embodiments of the present disclosure, other and further embodiments of the disclosure may be devised without departing from the basic scope thereof, and the scope thereof is defined by the claims that follow.

1. A cycloconverter configured for use with a power converter, comprising:
a bidirectional switch comprising a pair of Gallium-Nitride (GaN) High Electron Mobility Transistors; and
a Gate driver coupled to a gate of each of the pair of Gallium-Nitride (GaN) High Electron Mobility Transistors and configured to provide at least one of independent turn-on and turn-off outputs for implementing asymmetrical Gate drive characteristics, a voltage regulated supply to determine a gate turn-on voltage, and a gate turn-off voltage supply that can sink and source current.

2. The cycloconverter of claim 1, wherein the pair of Gallium-Nitride (GaN) High Electron Mobility Transistors are one of a Cascode GaN HEMT device, a gate injection transistor (GIT) GaN eHEMT device, or a Schottky Gate GaN eHEMT device.

3. The cycloconverter of claim 1, wherein the Gate driver comprises Resistors R₁ and R₂ connected to respective turn-on and turn-off outputs of the Gate driver.

4. The cycloconverter of claim 1, wherein the voltage regulated supply to determine the gate turn-on voltage is adjustable/programmable.

5. The cycloconverter of claim 1, wherein the gate turn-off voltage supply that can sink and source current is a Zener diode and voltage regulator, respectively.

6. The cycloconverter of claim 1, wherein the Gate driver is on a single PCB.

7. The cycloconverter of claim 1, wherein the gate of each of the pair of Gallium-Nitride (GaN) High Electron Mobility Transistors has a threshold voltage of about 0.7V to about 4V, a drive voltage of about 1.2V to about 12V, and a maximum voltage of about 16V to about 18V.

8. A power conversion system, comprising:
a converter;
a DC component coupled to a DC side of the converter;
a plurality of switches coupled to a primary winding of a transformer; and
a cycloconverter coupled to a secondary winding of the transformer and comprising:
a bidirectional switch comprising a pair of Gallium-Nitride (GaN) High Electron Mobility Transistors; and
a Gate driver coupled to a gate of each of the pair of Gallium-Nitride (GaN) High Electron Mobility Transistors and configured to provide at least one of independent turn-on and turn-off outputs for implementing asymmetrical Gate drive characteristics, a voltage regulated supply to determine a gate turn-on voltage, and a gate turn-off voltage supply that can sink and source current.

9. The power conversion system of claim 8, wherein the pair of Gallium-Nitride (GaN) High Electron Mobility Transistors are one of a Cascode GaN HEMT device, a gate injection transistor (GIT) GaN eHEMT device, or a Schottky Gate GaN eHEMT device.

10. The power conversion system of claim 8, wherein the Gate driver comprises Resistors R₁ and R₂ connected to respective turn-on and turn-off outputs of the Gate driver.

11. The power conversion system of claim 8, wherein the voltage regulated supply to determine the gate turn-on voltage is adjustable/programmable.

12. The power conversion system of claim 8, wherein the gate turn-off voltage supply that can sink and source current is a Zener diode and voltage regulator, respectively.

13. The power conversion system of claim 8, wherein the Gate driver is on a single PCB.

14. The power conversion system of claim 8, wherein the gate of each of the pair of Gallium-Nitride (GaN) High Electron Mobility Transistors has a threshold voltage of about 0.7V to about 4V, a drive voltage of about 1.2V to about 12V, and a maximum voltage of about 16V to about 18V.
